(19) United States
(12) Patent Application Publication
(10) Pub. No.: US 2005/0077539 A1
(43) Pub. Date: Apr. 14, 2005

(54) Semiconductor avalanche photodetector with vacuum or gaseous gap electron acceleration region

(76) Inventor: Jan Lipson, Cupertino, CA (US)

Correspondence Address: MORGAN, LEWIS & BOCKIUS, LLP., 2 PALO ALTO SQUARE, 3000 EL CAMINO REAL, PALO ALTO, CA, 94306, US

(21) Appl. No.: 10/920,495

(22) Filed: Aug. 17, 2004

Related U.S. Application Data
(60) Provisional application No. 60/495,903, filed on Aug. 18, 2003.

(51) Int. Cl. H01L 31/072

(52) U.S. Cl. 257/186; 257/438

(57) ABSTRACT

A semiconductor avalanche photodiode (APD) with very high current gain utilizes a small vacuum or gas filled gap which is used as a region to accelerate electrons to high energies. The APD has an absorption layer, a gap, and a multiplication layer. The absorption layer is adapted to generate electron-hole pairs upon absorbing light. The APD is adapted to generate an electric field in the gap and at an interface between the absorption layer and the gap. The electric field extracts electrons from the absorption layer into the gap and accelerates the extracted electrons while in the gap. The multiplication layer is adapted so that said accelerated electrons impinge on and cause a flow of secondary electrons within the multiplication layer.

### RELATED APPLICATION

This application takes the benefit of priority of U.S. Provisional Application No. 60/495,903, filed on Aug. 18, 2003, which provisional application is incorporated herein by reference in its entirety.

### TECHNICAL FIELD

The present invention relates to a photodetector which converts light to electrical signals, and amplifies the electrical signals in a nearly noise free process.

### BACKGROUND

Recent advances in the understanding of avalanche processes in avalanche photodiodes (APD's) have indicated that superior noise performance is possible if the carriers to be multiplied are first accelerated to an appreciable energy in a material wherein ionization is not expected to occur, prior to impacting on the material wherein ionization and multiplication is desired. In the article entitled “Low Noise Impact Ionization Engineered Avalanche Photodiodes Grown on InP Substrates,” S. Wang, J. B. Hurst, F. Ma, R. Sidhu, X. Sun, X. G. Zheng, A. L. Holmes, L. A. Coldren, and J. C. Campbell, IEEE Photonics Technology Letters, Vol. 14, NO. 12, p. 1722 (2002), the authors show how this understanding can be used to construct multiplication layers with advantageous noise properties. Material of larger bandgap is disposed next to the absorption region, with material of smaller band-gap disposed thereafter. Multiple layers or as few as two layers may be used to achieve this basic configuration. An advantageous design with reduced multiplication noise is presented in “Ultra-Low Noise Avalanche Photodiodes With a Centered-Well Multiplication Region,” Shuling Wang, Feng Ma, Xiaowei Li, Rubin Sidhu, XiaoGuang Zheng, Xiaoguang Sun, Archie L. Holmes, and Joe C. Campbell, IEEE Journal of Quantum Electronics, Vol. 39, NO. 2, p. 375 (2003). In each of these instances, the material of larger bandgap acts as a region in which carriers can be accelerated without ionization. Upon impact in regions of smaller bandgap, ionization is expected to occur quickly and in a deterministic manner, avoiding the stochastic multiplication processes that are the major source of noise in previous work.

Whereas such APD's possess very good noise multiplication performance for small values of the current multiplication (M), the noise increases precipitously at higher values. In consequence, ultimate sensitivities for such applications as single photon counting or ultra-high sensitivity communications receivers are still difficult to achieve as the multiplied signal is not large enough to completely overcome the noise of subsequent electronic amplifiers. Therefore it would be desirable to have a device that could operate with much higher multiplication.

### SUMMARY

A semiconductor avalanche photodiode (APD) with very high current gain utilizes a small vacuum or gas filled gap which is used as a region to accelerate electrons to high energies. The APD has an absorption layer, a gap, and a multiplication layer. The absorption layer is adapted to generate electron-hole pairs upon absorbing light. The photodiode is adapted to generate an electric field in the gap and at an interface between the absorption layer and the gap. The electric field extracts electrons from the absorption layer into the gap and accelerates the extracted electrons while in the gap. The multiplication layer is adapted so that the accelerated electrons impinge on and cause a flow of secondary electrons within the multiplication layer.

### BRIEF DESCRIPTION OF THE DRAWINGS

Embodiments of the invention are described below in conjunction with the accompanying drawings.

FIG. 1A is a drawing of an APD having a vacuum or gaseous gap adapted to act as an electron acceleration region.

FIG. 1B is a drawing of an APD having a vacuum or gaseous gap adapted to act as an electron acceleration region and further including a reverse bias junction in an insulating layer.

FIG. 2 is drawing of an APD having quantum dots on a surface of an absorption region that borders the gap in the APD of FIG. 1.

FIG. 3 is a drawing of an APD having an inter-layer contact.

FIG. 4 is a drawing of an APD having multiple acceleration regions and multiplication regions.

FIG. 5 is a drawing of an APD having multiple acceleration regions and multiplication regions, wherein quantum dots are included on a surface within one or more of the acceleration regions.

FIG. 6 is a drawing of an APD having a vacuum or gaseous gap that has a bowed upper surface.

FIG. 7 is a drawing of an APD having multiple quantum well layers.

Like reference numbers refer to corresponding parts throughout the drawings.

### DETAILED DESCRIPTION OF EMBODIMENTS

Semiconductor photodetectors make use of material systems appropriate to wavelength of the light to be detected. The optimal juxtaposition of the various layers and their specification depends on the application (i.e., the wavelength and intensity of the light to be detected) and the materials selected. While describing various embodiments, considerations for choosing the layers of the semiconductor photodetector will be discussed. A specific example appropriate to a specific range of wavelengths will be shown to illustrate the application of these principles.

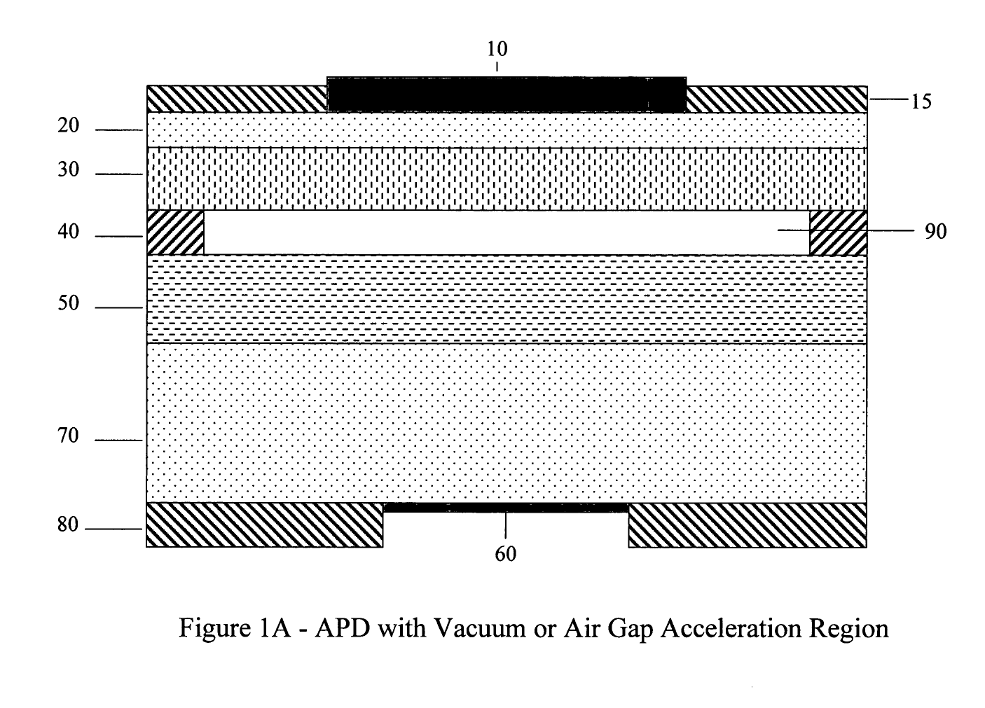

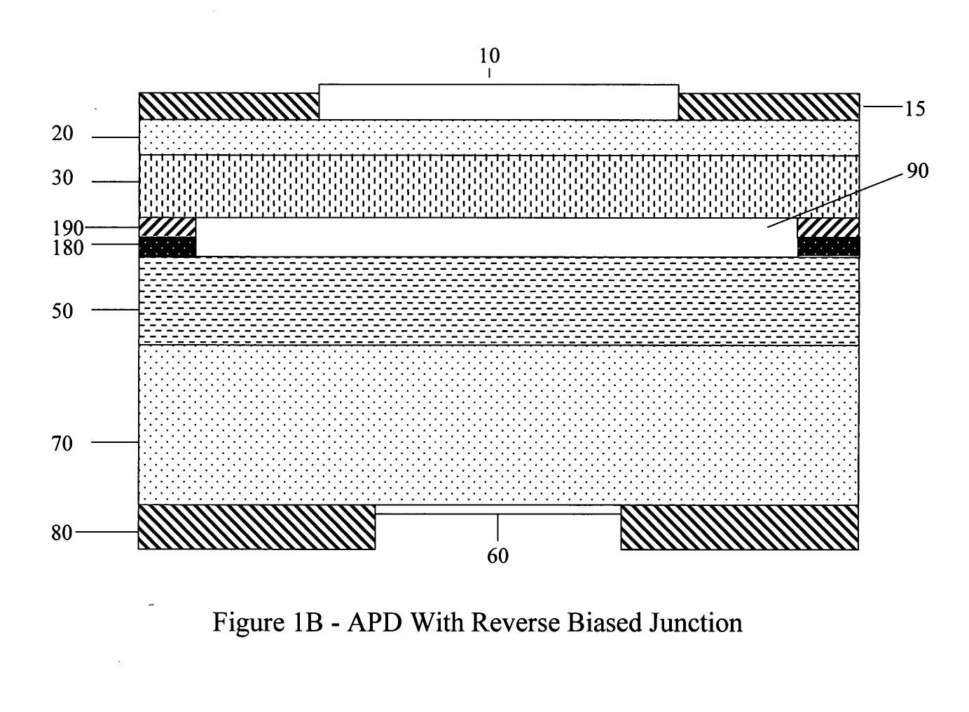

Referring to FIGS. 1A and 1B, one embodiment of an avalanche photodiode includes insulating material 40, an absorption region 50, and a vacuum or gas filled gap 90. Other layers of the device may be chosen in accordance with considerations that are well discussed in the literature and are well known to those skilled in the art of photodiode design.

Layer 40 prevents any appreciable conduction of electrons across the gap 90. Such leakage will be observed in the form of undesirable dark current. There are in general two suitable choices for layer 40: a dielectric material or a reverse biased junction. If a dielectric material is used, a high resistivity material should be chosen. In addition, a high break-down voltage is also desirable. Materials (e.g., zinc selenide) in which the field required to extract an electron is very high (e.g., greater than 70 volts/μm) are preferred. When layer 40 is a reverse biased junction, the materials used to form the junction should not conduct an appreciable number of carriers at the anticipated operating voltages. FIG. 1B illustrates a reverse biased junction wherein layer 190 is doped with a N-type dopant and layer 180 is doped with a P-type dopant. The junction between layers 190 and 180 is reverse-biased when layer 10 has a positive voltage relative to layer 60.

Layer 50 should be a material from which electrons are extracted at moderate to low electric fields (e.g., less than 50 volts/μm) so that the voltage required can be minimized. In addition, the doping of layer 50 should be arranged so that the electron density is relatively low (e.g., below 10¹⁷ cm⁻³, and preferably less than 10¹⁶ cm⁻³) at the temperatures at which the device is expected to be operated (e.g., between −40° C. and 100° C.). That will minimize the dark current of the device. Although intrinsic doping levels are commonly chosen, a low level of P-doping (e.g., less than 10¹⁷ cm⁻³) is also a reasonable choice.

The gap 90 should either be a vacuum or should be filled with a gas. The gap length, defined as the distance between the absorption region 50 and the multiplication layer 30 is chosen such that the electric field will be high enough to extract primary electrons from the absorption region 50, at voltages which are acceptable in each application. The gap length should not be so thin that the preferential crystal plane etching processes that produce the gap 90 become inapplicable, or so thin that the gap 90 collapses because of high forces at atomic scale distances. The minimum distance depends on material choices and differential etch rates for the crystal planes, and may be ascertained for each proposed material system. If the gap 90 is filled with gas, it is desirable that the mean free path for electron collisions be longer than the gap length. Generally speaking, for the same pressure, low Z number gases such as helium will have longer mean free paths for collisions. Nevertheless, practical gaps of the order of 100 nm can be used with a gap filled with nitrogen or air at a pressure of approximately one atmosphere. More generally, in practice, the gap 90 will typically have a gap length between about 50 nm and 300 nm.

The foregoing illustrates the use of correct design principles in a specific example. Note that even in this example other choices are feasible and specific material choices, layer thicknesses, and doping levels are not critical to the new teachings of this invention.

Referring to the embodiment of FIG. 1A, layer 10 is a P-contact for the device, which is isolated from the other layers by dielectric layer 15. Layer 20 is a strongly doped P-type semiconductor which can be InGaAs, whereas layer 30 is the multiplication region (also called the multiplication layer), which has been chosen to be a compatible lightly doped (e.g., less than 10¹⁸ cm⁻³, and preferably less than 10¹⁷ cm⁻³) N-type or intrinsic semiconductor. In some embodiments, the multiplication layer 30 is formed from InP, InGaAs, or InGaAlAs. Layer 40 is an insulating material of very high resistivity and can be chosen to be a dielectric. A good choice for layer 40 is ZnSe (zinc selenide) which also has a high breakdown voltage for a given thickness (e.g., a breakdown voltage of greater than about 20 volts for a thickness of about 100 nm). Other insulating materials may be used in other embodiments.

Layer 50 is an absorption layer (also called the absorption region) which has been chosen to have a band-gap smaller than the energy of the least energetic photon it is desired to detect. In some embodiments, layer 50 is formed from InGaAs, and is doped P with a relatively low concentration (less than 10¹⁸ cm⁻³, and preferably less than 10¹⁶ cm⁻³), such that electrons are the minority carrier. This is advantageous in order to assure that the minimum number of electrons are present in the conduction band from sources not associated with the detection process. In particular, such an arrangement minimizes the density of electrons in the conduction band due to thermionic emission. Such free electrons could act as a source of dark current, which is the current from the detector when no illumination is provided. In other embodiments, layer 50 is formed from intrinsic semiconductor material, with minimal intentional doping. Layer 70 is the substrate. In some embodiments, layer 70 is an N-type InP semiconductor, and layer 80 is an N-contact. Gap 90 is a vacuum gap, or a gap which contains a gas. In one embodiment, the gap has a gap length of approximately 200 nm, and is filled with helium at approximately 1 atmosphere of pressure.

When a voltage is applied between layers 10 and 80, electric fields will be present in the materials of the device, and in the gap 90. It is desirable that a substantial fraction of the voltage potential be dropped across the gap 90 for the purpose of extracting and accelerating electrons from the absorption region 50. Dimensions, materials and doping concentrations of the various regions or layers of the device should be chosen such that some voltage is also dropped across the absorption region 50 for the purpose of causing electrons to drift rapidly across the absorption region 50 to the interface between the -absorption region 50 and the gap 90. A substantial voltage drop across layer 30 (i.e., the multiplication region or layer) is also desired to create additional secondary electrons by ionization arising from the bombardment of the surface of layer 30 nearest the gap 90 by electrons that are accelerated through the gap 90. In one example, a voltage in a range between about 40 volts and about 60 volts is applied across the device. Approximately 25 percent of the voltage drop is across the gap 90, about 5 percent is across the absorption region 50 and about 70 percent is across the multiplication layer 30. The amount of voltage drop and the percentages of the voltage drop across the various layers and regions will vary from one embodiment to another.

When a photon is incident on the detector, it will be preferentially absorbed in layer 50, generating an electron-hole pair. In FIG. 1A the photons are assumed to be incident from the bottom, passing through layer 60, which is an anti-reflection coating. However, this is only a representative example and in general light can impinge on the detector from either the top or the bottom. The electric field within the absorption region 50 causes the electrons to drift towards the gap 90. If the field at the interface between the absorption region 50 and the gap 90 is sufficient, electrons are extracted from the absorption region 50 into the gap 90. The strength of the electric field required at this interface depends greatly on the material used to form the absorption region 50. For some semiconductors it is in the range of 50 V/μm. Upon extraction into the gap 90, an electron will gain an energy, which is given by the voltage drop across the gap (assuming no collisions occur in the gap), less the energy required to extract the electron, which is referred to as the work function of the material. If the energy of the electrons impinging on the multiplication layer 30 is higher than that required for ionization, secondary electrons will be generated.

It is very noteworthy that semiconductor acceleration regions (as opposed to the gap 90 of the present invention) are very deficient in providing sufficiently energetic electrons to the multiplication region. At best they give the electrons a small amount of initial energy, which is then augmented by the large fields in the multiplication layer. The reason is that the saturated drift velocity for electrons in most practical materials is simply very low. In typical semiconductors, the drift velocity is of the order of 10⁷ cm/s and the corresponding energy is a very small fraction of an electron volt. No such limitations exist with the vacuum or gaseous gap 90 of the present invention. The initial electron energy can be several orders of magnitude larger if desired, the energy depending only on the voltage that is provided across the gap 90.

The statistics of the multiplication process are also important to key device characteristics. Electrons impinging on the multiplication layer 30 already have energy sufficient to promptly ionize the material of the multiplication layer 30. Such ionization will occur quite near the surface of the multiplication layer 30. Secondary electrons so generated will also have significant energy and will preferentially have substantial momentum in the forward direction. The subsequent avalanche will be highly deterministic with each primary electron contributing substantially a similar number of secondary electrons, such that the ratio of the mean number of secondary electrons to the standard deviation is large. In addition, the ratio of secondary electrons to holes is typically very high (e.g., greater than 10). This is to be contrasted with the usual situation in APD's where the initial secondary carriers may be created in a substantial volume of material, some of which is not near the surface of the multiplication layer 30. The energy being low, an undesirably large fraction of the secondary carriers may be scattered in the reverse direction or at least not in the forward direction. The resulting cascade is noisy. The number of secondary carriers generated from each primary carrier will vary considerably on a purely statistical basis. The pulse is also dispersed in time, and the tail of the pulse contains a great deal of noise as it is largely drawn from back-scattered slow moving carriers. The present invention substantially eliminates this source of signal noise.

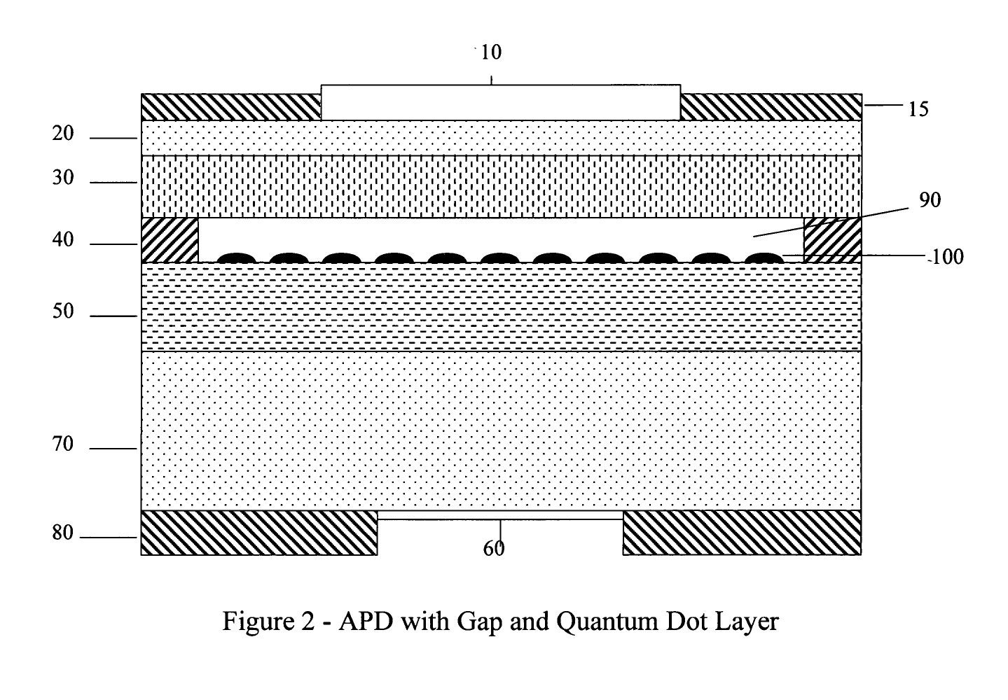

In FIG. 2, a layer of quantum dots 100 is added to the absorption layer 50, at the interface adjacent to the gap 90. The quantum dots, 100 are preferably formed using a well-known self-assembly technique. A self-assembly technique is discussed, for example, in the article entitled “Self-Assembled Semiconductor Structures: Electronic and Optoelectronic Properties,” Hongtao Jiang and Jasprit Singh, IEEE Journal of Quantum Electronics, vol. 34, No. 7, July 1998, which is hereby incorporated by reference. A suitable choice of material for such dots is InAs grown on an InGaAs absorbing layer. The purpose of the quantum dots is two fold. First, the dots concentrate the electric field in the device, creating regions near their apex where the field is significantly higher than the average field. As a result, the average field, and hence the voltages required for extraction can be reduced. Secondly, if the gap between the valence band and the ground state in the conduction band of the quantum dots is similar to the bandgap of the absorption layer 50, then reduced thermionic emission may be anticipated because the density of excited states in the conduction band is less than that of the bulk material in absorption layer 50. As a result there are fewer states that thermionically excited electrons can occupy. The size of the quantum dots may be advantageously chosen such that the equivalent band-gap is similar to that of the absorption layer 50. In one embodiment, the size of the quantum dots is approximately 30 nm in diameter, and about 10 nm high, and more generally the quantum dots will typically be in a range between about 10 nm and about 80 nm in diameter and between about 3 nm and about 20 run high.

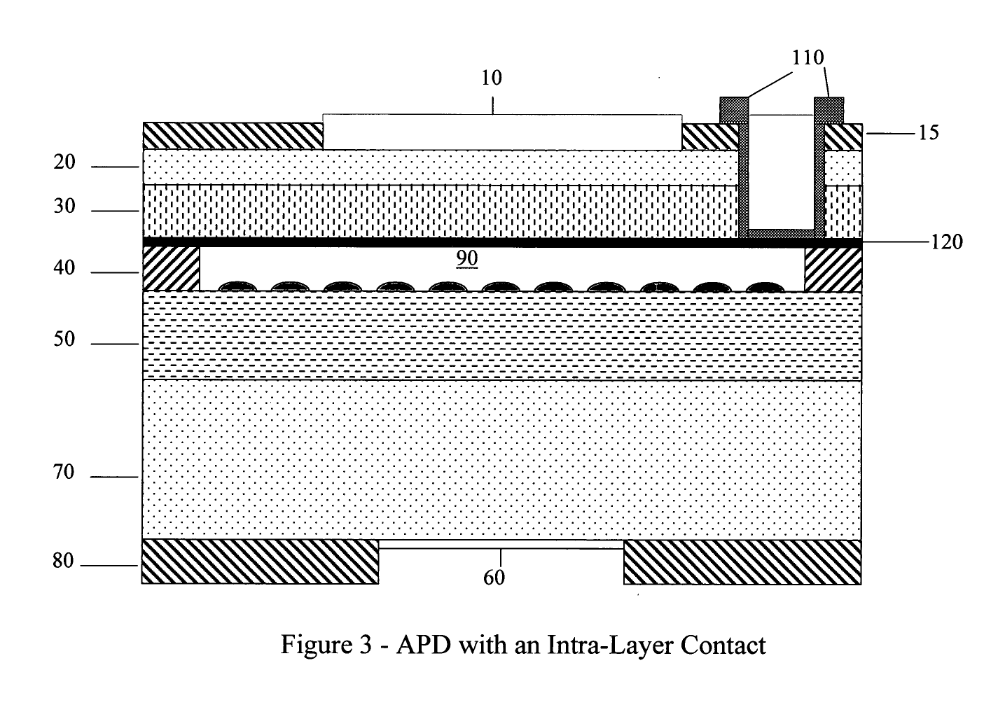

In FIG. 3, an APD having a third contact 110 is shown, permitting a separately adjustable voltage to be applied to the APD. Layer 120 is a highly doped semiconductor. In some embodiments, layer 120 has the same composition as the multiplication region 30, differing only in its higher doping. The third contact 110 is a metal contact in a via hole, providing a continuous electric contact with layer 120. Other contact geometries such as lateral contacting are possible. The ability to provide a separate bias voltage intermediate to the voltages applied to the top and bottom contacts of the APD permits considerably more design freedom in choosing the dimensions, materials, and doping levels of the various layers of the device. Using the third contact 110, the electric field can be separately optimized for at least one region of the device. The contact 110 need not be placed at the interface between the multiplication layer 30 and the gap 90 as shown in FIG. 3. In other embodiments, one or more contacts can be inserted at other locations within the device so as to provide control over the electric field in other portions of the device.

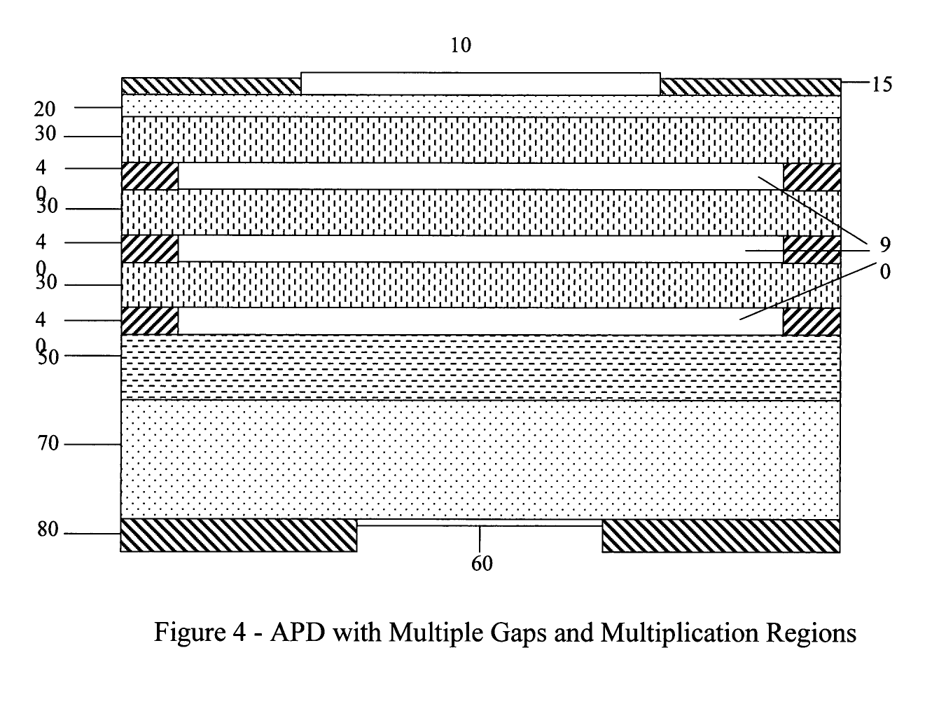

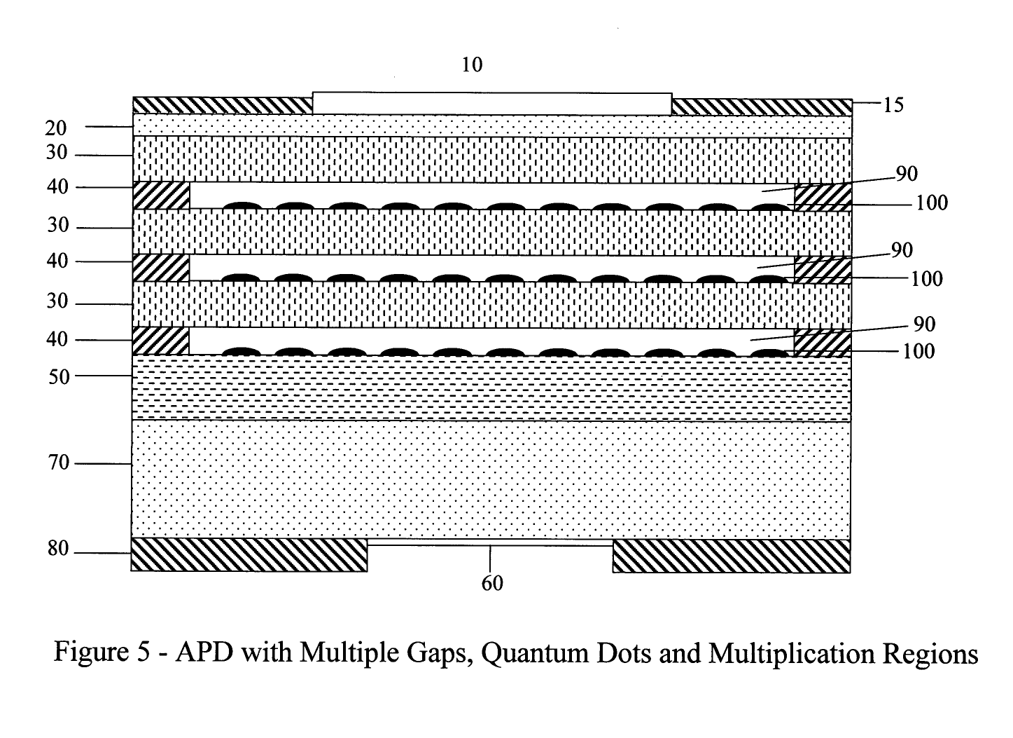

FIG. 4 shows an APD in which the device configuration described above is extended to an APD having multiple gaps 90 and multiple multiplication layers 30. The principles of operation are identical to those previously described. However, current gain will be obtained in each multiplication layer 30, thereby providing higher total gain than the devices of FIGS. 1 through 3. This is very advantageous when detecting small signals, as the current multiplication gain is a very low noise process, and in general greatly superior to electronic gain available in electronics based amplifiers. In alternate embodiments, one or more of the multiple gaps 90 may include quantum dots 100 on a surface of the gap, as shown in FIG. 5.

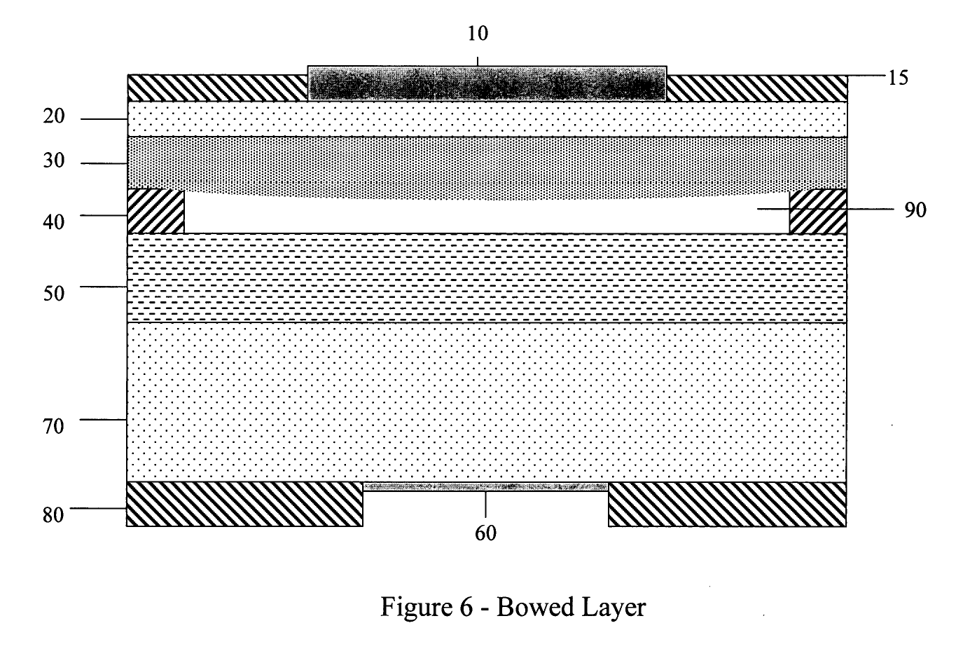

Referring to FIGS. 1 through 3, the gap 90 (or the multiple gaps of FIGS. 4 and 5) need not be of homogenous length or uniform. As a result of Van Der Waals forces and electro-static attraction, there is a tendency for the two exposed surfaces of the gap 90 to attract each other, resulting in a diminished gap length near its center relative to the gap length at the lateral areas of the gap 90. For example, as illustrated in FIG. 6, layer 30 may bow into the gap 90. The thickness of the layers above the gap 90 (e.g., layers 15, 20 and 30) can be chosen to control this bowing with the object of controllably increasing the field at the center. The combined thickness of the layers 15, 20, 30 above the gap 90 may be a couple to a few microns, such that the bowing of these layers reduces the gap length in the center of the gap 90. This effect may be used to yield a device which is more immune to surface irregularities as electron extraction occurs preferentially where the electric field is greatest, which in this case is in the middle of the gap 90.

It is also possible to deliberately produce a device where the gap length at the middle of the gap 90 can be controlled by the applied voltages, using the resulting electrostatic forces to deflect the materials forming the opposing sides of the gap 90. The forces arise from the presence of charge polarization, as is obtained in any dielectric material, in the presence of the electric field. A controlled amount of bowing can be designed into such a device by choosing the dimensions of the gap and appropriate elastic moduli to obtain the desired deflection. As noted above, the combined thickness of the layers above the gap 90 may be a couple to a few microns. The bowing of these layers as controlled by the applied voltages significantly reduces the gap length in the center of the gap 90, for example by 10 to 100 nm when the full gap length at the distal portions of the gap 90 is in the range of 50 to 300 nm (i.e., the gap length is reduced by the bowing by about 20 to 70 percent at the center of the gap 90). In some embodiments, an adjustable voltage can be applied using one or more metal contacts at suitable locations of the device to control the bowing of the layers above the gap 90, as described with respect FIG. 3.

As the voltage is increased, both the bowing and the electric field increase. The electric field is a non-linear function of the voltage because the gap 90 is reduced in conjunction with increasing voltage. It is possible to provide a voltage which produces precisely a desired electric field within the range of allowed variations for the bowing and the voltage. This is advantageous in order to optimize the magnitude of the voltages required to extract electrons.

The invention is not limited to a detector for detecting radiation in any particular part of the electromagnetic spectrum. In particular, detectors for detecting infrared light may be implemented using avalanche photodiodes, as described above, having multiple quantum dot layers or multiple quantum wells in the absorption layer. Such detectors generate primary electrons in the absorption region 50 using inter-sub-band transitions that generally occur in the mid- to far-infrared portion of the electromagnetic spectrum. An inter-sub-band transition is an event wherein an incident photon excites a charged carrier from one state within a single band (a band being either the valence or conduction band) to a higher excited state within the same band. Such transitions are advantageous for absorption at wavelengths that are longer than can be easily absorbed by most commonly available semiconductors when such absorbers rely on transitions from the valence to conduction bands of such semiconductors.

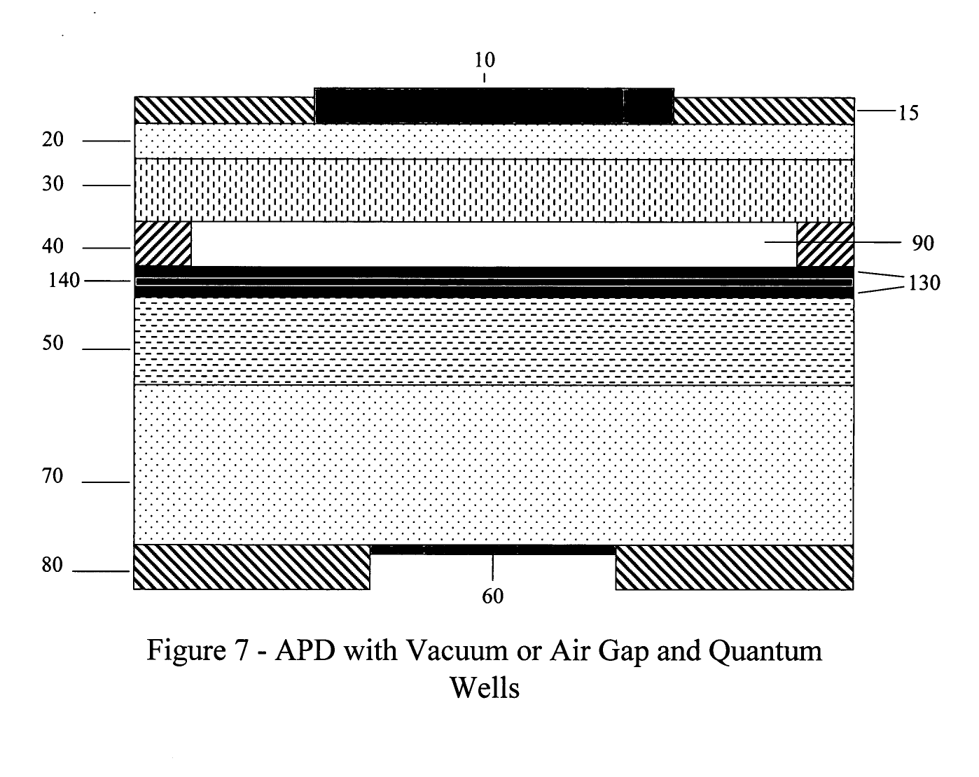

FIG. 7 illustrates an embodiment of an APD having multiple quantum wells. A quantum well consists of a well layer 140 sandwiched between two barrier layers 130. Although one quantum well layer is illustrated in FIG. 7 by layers 130 and 140, multiple quantum wells will typically be used. The one or more quantum well layers are located between the absorption layer 50 and the gap 40. The quantum well layer(s) may include, for example, a P- or N-doped InGaAs well layer 140, while the barrier layers 130 typically include an undoped semiconductor material such as AlGaAs or GaAs. The thickness of well layer(s) 140 is typically less than about 10 nm, and preferably less than about 8 run. Barrier layers 130 typically have a thickness that is greater than about 30 nm, and preferably in a range between about 40 m and about 50 nm. Quantum wells for inter-sub-band transitions are discussed, for example, in the article entitled “Investigation of Broad-Band Quantum-Well Infrared Photodetectors for 8-14-μm Detection,” by J. Chu, Sheng S. Li, and A. Singh, IEEE Journal of Quantum Electronics, vol. 35, No. 3, March 1999, which is hereby incorporated by reference.

Furthermore, the detection of X-rays or gamma-rays is also feasible using the avalanche photodiodes described above, as such radiation causes the creation of primary electrons. Particle forms of radiation such as alpha and beta radiation may also induce creation of detectable primary electrons, and improved detection can still be expected because of the superior multiplication process. Absorption materials not dissimilar to those used for visible or near infrared radiation are also appropriate choices for such detectors.

1. A semiconductor avalanche photodiode, comprising:
an absorption layer, a gap, and a multiplication layer;
wherein
the absorption layer is adapted to generate electron-hole pairs upon absorbing light;
the photodiode is adapted to generate an electric field in the gap and at an interface between the absorption layer and the gap, wherein the electric field extracts electrons from the absorption layer into the gap and accelerates the extracted electrons while in the gap;
the multiplication layer is adapted so that the accelerated electrons impinge on and cause a flow of secondary electrons within the multiplication layer.

2. The avalanche photodiode of claim 1, wherein the gap comprises either a vacuum or a region occupied by a gas.

3. The avalanche photodiode of claim 1, further comprising a quantum dot layer positioned in the gap at the interface between the absorption layer and the gap.

4. The avalanche photodiode of claim 1, including first and second contacts for applying a supply voltage and receiving a current, the avalanche photodiode further comprising a third contact adapted to control the electric field in the gap.

5. The avalanche photodiode of claim 1, further comprising multiple multiplication layers and gaps, each additional multiplication layer providing a current gain of greater than 1 with respect the current incident upon it.

6. The avalanche photodiode of claim 1, wherein the absorption layer is adapted to be sensitive to alpha, beta, or gamma radiation, and to emit electrons when such radiation is incident upon it.

7. The avalanche photodiode of claim 1, wherein the gap is adapted to have a gap length near the center of the gap that is smaller than a gap length at a distal region of the gap, such that electrons are preferentially extracted from near the center of the gap into the multiplication layer.

8. The avalanche photodiode of claim 1, wherein the avalanche photodiode is adapted to adjust a length of the gap by the application of a voltage, such that the electrostatic forces arising from the application of said voltage deflects the materials so as to reduce the gap length to a desired value.

9. The avalanche photodiode of claim 1, wherein the gap is filled with a gap filling gas, the gap filling gas comprising helium.

10. The avalanche photodiode of claim 1, wherein the gap is filled with a gap filling gas, the gap filling gas comprising nitrogen.

11. The avalanche photodiode of claim 1, wherein the gap is filled with a gap filling gas, the gap filling gas comprising air.

12. The avalanche photodiode of claim 1, wherein the absorption region includes multiple quantum well layers.

13. The avalanche photodiode of claim 1, wherein the absorption region includes multiple layers of quantum dots.

14. The avalanche photodiode of claim 1, including an insulating layer comprising a dielectric.

15. The avalanche photodiode of claim 14, where the dielectric is zinc selenide.

16. The avalanche photodiode of claim 1, including a reverse biased junction adjacent the gap.
